(19) United States
(12) Patent Application Publication
(10) Pub. No.: US 2002/0195620 A1
(43) Pub. Date: Dec. 26, 2002

(54) Compound semiconductor device having heterojunction bipolar transister and other component integrated together and process for fabrication thereof

(75) Inventors: Masahiro Tanomura, Tokyo (JP); Hidenori Shimawaki, Tokyo (JP); Takaki Niwa, Tokyo (JP); Koji Azuma, Tokyo (JP); Naoto Kurosawa, Tokyo (JP)

Correspondence Address: PATENT GROUP, CHOATE, HALL & STEWART, EXCHANGE PLACE, 53 STATE STREET, BOSTON, MA, 02109, US

(73) Assignee: NEC Compound Semiconductor Devices, Ltd.

(21) Appl. No.: 10/164,093

(22) Filed: Jun. 5, 2002

(30) Foreign Application Priority Data
Jun. 25, 2001 (JP) 2001-190652

(51) Int. Cl. H01L 31/0328; H01L 31/072; H01L 31/0336; H01L 31/109; H01L 21/8222; H01L 21/331; H01L 27/102; H01L 27/082; H01L 29/70; H01L 31/11

(52) U.S. Cl. 257/197; 257/577; 438/314

(57) ABSTRACT

A heterojunction bipolar transistor and a protective PIN diode are implemented by two multi-layered compound semiconductor structures epitaxially grown on respective regions of a semi-insulating substrate; the entire upper surface of the base layer is covered with the emitter layer, and the base electrode on the emitter layer projects through the emitter layer into the base layer; although the two multi-layered compound semiconductor structures are covered with a passivation layer, the emitter layer prevents the base layer from direct contact with the passivation layer so that leakage current hardly flows between the base and the emitter.

### FIELD OF THE INVENTION

This invention relates to a compound semiconductor device and, more particularly, to a compound semiconductor device having a heterojunction bipolar transistor and another circuit component integrated together on a single substrate and a process for fabrication thereof.

### DESCRIPTION OF THE RELATED ART

A heterojunction bipolar transistor is well responsive to a high frequency signal so that circuit designers incorporate the heterojunction bipolar transistor in various sorts of high-frequency circuits. When a designer employs discrete type heterojunction bipolar transistors, the designer prepares a circuit board, and arranges the discrete-type heterojunction transistors on the circuit board together with other circuit components. If the heterojunction bipolar transistor and other circuit components are integrated on a semiconductor substrate, the electric circuit becomes simple, and the production cost is reduced. However, if the fabrication steps for the other circuit components are arranged in serial to the fabrication steps for the heterojunction bipolar transistors, the additional steps make the process sequence complicated, and the production cost is increased. From the viewpoint of the fabrication process, it is desirable to fabricate the other circuit components concurrently with the heterojunction bipolar transistor.

The heterojunction bipolar transistor is weak in the anti-surge characteristics. If strong static surge is reversely applied between the collector layer and the emitter layer, the heterojunction bipolar transistor is liable to be broken down. A countermeasure against the static surge is to insert a protective diode between the collector and the emitter. The protective diode discharges the static charge. The protective diode surely enhances the reliability of the heterojunction bipolar transistor. From the above-described viewpoint of the fabrication process, the protective diode is to be integrated on a semiconductor substrate together with the heterojunction bipolar transistor.

From the viewpoint of improvement in the fabrication process, a compound semiconductor device is proposed in Japanese Patent Application laid-open No. 2000-357695. The prior art compound semiconductor device includes a heterojunction bipolar transistor and a p-n junction diode connected between the collector and the emitter of the heterojunction bipolar transistor.

The heterojunction bipolar transistor and the protective diode are integrated on a single semiconductor substrate. The compound semiconductor layers are shared between the collector/base of the heterojunction bipolar transistor and the anode/cathode of the protective diode. When static charge is applied to the emitter of the heterojunction bipolar transistor, the protective diode permits the static charge to flow, and prevents the heterojunction bipolar transistor from the damage. The compound semiconductor substrate is shared between the heterojunction bipolar transistor and the protective diode, and the collector and emitter are formed concurrently with the anode/cathode. Thus, the first prior art compound semiconductor device makes the fabrication process simple, and the production cost is reduced.

Another prior art compound semiconductor device is disclosed in Japanese Patent Application laid-open No. 8-255838. The monolithic multi-functional integrated circuit device disclosed in the Japanese Patent Application laid-open is shown in FIG. 1.

The prior art compound semiconductor device disclosed in Japanese Patent Application laid-open No. 8-255838 is fabricated on a compound semiconductor substrate 301, and comprises a heterojunction bipolar transistor 341 and a PIN (P-type semiconductor layer-Intrinsic semiconductor layer-N-type semiconductor layer) diode 342. An n-type compound semiconductor layer is grown on the compound semiconductor substrate 301, and an isolating region 311 penetrates the n-type compound semiconductor layer so as to define active regions assigned to the heterojunction bipolar transistor 341 and the PIN diode 342, respectively. Though not shown in FIG. 1, the heterojunction bipolar transistor 341 and the PIN diode 342 are covered with a passivation layer.

The n-type compound semiconductor layer in the active region assigned to the heterojunction bipolar transistor 341 serves as a sub-collector layer 302. A collector layer 303 is laminated on the sub-collector layer 302, and a collector electrode 310 is formed on the peripheral area of the sub-collector layer 302. A base layer 304 is laminated on the collector layer 303, and forms the collector-base junction together with the collector layer 303. The base layer 304 is overlaid with an emitter layer 306, and forms an emitter-base junction together with the emitter layer 306. A base electrode 309 is formed in the peripheral area of the base layer 304, and an emitter electrode 308 is formed on the upper surface of the emitter layer 306.

The n-type compound semiconductor layer in the active region assigned to the PIN diode 342 serves as an n-type region 312. An intrinsic region 313 is laminated on the n-type region 312, and an anode 320 is formed in the peripheral area of the n-type region 312. The intrinsic region 313 is overlaid with a p-type region 314, and a cathode 319 is formed on the upper surface of the p-type region 314.

The PIN diode 342 is connected between the base layer 304 and the emitter layer 306, and an input signal is applied to the base electrode. While the input signal is swinging the potential level within the normal range, the PIN diode 342 does not permit any current to flow therethrough. However, when the input signal swings the potential out of the normal range, the excess potential is discharged through the PIN diode 342. Thus, the PIN diode 342 prevents the heterojunction bipolar transistor from the excess load.

Yet another compound semiconductor device is disclosed in Japanese Patent Application laid-open No. 5-90287. A heterojunction bipolar transistor and a PIN diode are integrated together in the Japanese Patent Application laid-open. A substrate is prepared, and an active region and another active region are respectively assigned to the heterojunction bipolar transistor and the PIN diode.

Active regions are defined in a substrate. One of the active regions is assigned to a heterojunction bipolar transistor, and another active region is assigned to a PIN diode. A sub-collector region of the first conductivity type is formed on the active region assigned to the heterojunction bipolar transistor, and a region of the first conductivity type is also formed in the active region assigned to the PIN diode. An intrinsic semiconductor layer is grown on the sub-collector region and the region of the first conductivity type. The intrinsic semiconductor layer partially serves as a collector region, and partially as an intrinsic region. Compound semiconductor of the second conductivity type is grown on the intrinsic layer. The part of the compound semiconductor layer over the region assigned to the heterojunction bipolar transistor serves as a base region, and another part of the compound semiconductor layer over the region assigned to the PIN diode serves as a second conductivity region. Compound semiconductor of the first conductivity type is grown on the compound semiconductor layer of the second conductivity type. The compound semiconductor layer of the first conductivity type is partially etched away so as to leave an emitter layer over the region assigned to the heterojunction bipolar transistor, and a part of the emitter layer is concurrently etched away. The sub-collector region, collector region, base region and emitter region form in combination the heterojunction bipolar transistor, and the first conductivity region, intrinsic region and second conductivity region as a whole constitute the PIN diode. Finally, an isolating region is grown at the boundary between the heterojunction bipolar transistor and the PIN diode, and the heterojunction bipolar transistor and the PIN diode are covered with a passivation layer. The dimensions of circuit components, volume of the device and production cost are reduced through the prior art process.

Still another prior art heterojunction bipolar transistor is disclosed in Japanese Patent Application laid-open No. 3-64929. The heterojunction bipolar transistor and a PIN diode are integrated on a single compound semiconductor substrate. The compound semiconductor substrate offers a collector region to the heterojunction bipolar transistor and a cathode region to the PIN diode. The collector is overlaid with another sort of compound semiconductor layer, which is shared between the base region and an anode region of the PIN diode. The base region in turn is overlaid with an emitter region of yet another sort of compound semiconductor, and the heterojunction bipolar transistor and the PIN diode are covered with a passivation layer. The PIN diode is connected between the base region and the collector region or between the collector region and the emitter region so as to prevent the heterojunction bipolar transistor from inverse surge.

Thus, all the prior art compound semiconductor devices are designed in the form of integrated circuit. However, a problem is encountered in all the prior art compound semiconductor devices in that leakage current flows between the base electrode 309 and the emitter electrode 308 through the passivation layer. As seen in FIG. 1, the base region 304 has the upper surface wider than the lower surface of the emitter region 306, and the remaining upper surface of the base region 304 is directly held in contact with the passivation layer. Although the passivation layer is formed of insulating material, the passivation layer is held in contact with the base region 304 as well as the emitter region 306. In other words, the base region 304 is not only held in contact with the emitter region 306 at the emitter-base junction but also connected through the passivation layer to the emitter region 306. The emitter region 306 is patterned from the compound semiconductor layer. When the etchant is active on the compound semiconductor layer over the active region assigned to the PIN diode 342, the compound semiconductor layer is further etched from the peripheral area of the base region 304, and the base region 304 is partially exposed. Even though the emitter-base junction is reversely biased, the passivation layer provides a leakage path so that a small amount of current flows between the emitter electrode 308 and the base electrode 309.

### SUMMARY OF THE INVENTION

It is therefore an important object of the present invention to provide a compound semiconductor device, the structure of which is effective against leakage current unintentionally flowing through a passivation layer.

It is also an important object of the present invention to provide a process for fabricating the compound semiconductor device.

In accordance with one aspect of the present invention, there is provided a compound semiconductor device fabricated on a substrate comprising a first multi-layered compound semiconductor structure grown on a first region of the substrate assigned to a heterojunction bipolar transistor and providing a base region grown on a collector region for forming a collector-base junction and having an upper surface and an emitter region grown on the base region for forming a base-emitter junction substantially as wide as the upper surface of the base region, the heterojunction bipolar transistor further including a collector electrode electrically connected to the collector region, a base electrode formed on the emitter region and penetrating therethrough so as to be in contact with the base region and an emitter electrode electrically connected to the emitter region, a second multi-layered compound semiconductor structure grown on a second region of the substrate assigned to another element and electrically isolated from the first multi-layered compound semiconductor structure, and a passivation layer covering the first and second multi-layered compound semiconductor structures.

In accordance with another aspect of the present invention, there is provided a process for fabricating a compound semiconductor device comprising the steps of a) epitaxially growing a plurality of compound semiconductor layers a substrate, b) shaping the plurality of compound semiconductor layers into plural multi-layered compound semiconductor structures on respective regions of the substrate so as to form an emitter electrode electrically connected to an emitter region incorporated in one of the plural multi-layered compound semiconductor structures, a base electrode formed on the emitter region layered on an entire upper surface of a base region and penetrating the emitter region so as to be in contact with the base region, a collector electrode electrically connected to a collector region and other electrodes connected to certain compound semiconductor regions of another of the plural multi-layered compound semiconductor structures, and c) covering the plural multi-layered compound semiconductor structure with a passivation layer so that the emitter region prevents the entire surface of the base region from being in contact with the passivation layer.

### BRIEF DESCRIPTION OF THE DRAWINGS

The features and advantages of the compound semiconductor device and the fabrication process will be more clearly understood from the following description taken in conjunction with the accompanying drawings, in which

FIG. 1 is a cross sectional view showing the structure of the prior art compound semiconductor device,

FIG. 2 is a cross sectional view showing the structure of a compound semiconductor device according to the present invention,

FIGS. 3A to 3H are cross sectional views showing a process sequence for fabricating a compound semiconductor device according to the present invention,

FIG. 4 is a circuit diagram showing the connections between circuit component elements of the compound semiconductor device,

FIG. 5 is a schematic cross sectional view showing the connections between the electrodes of the circuit component elements, and

FIG. 6 is a cross sectional view showing the structure of another compound semiconductor device according to the present invention.

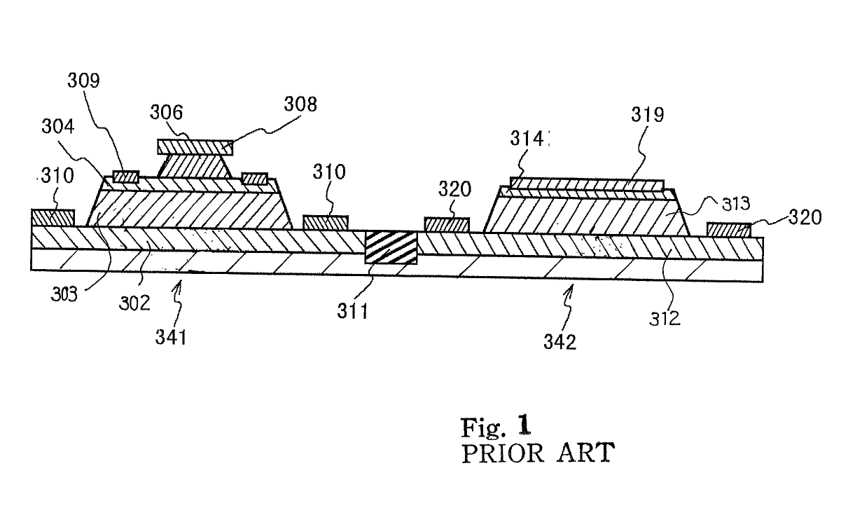

### DESCRIPTION OF THE PREFERRED EMBODIMENTS

Although description is hereinbelow made on compound semiconductor devices in the gallium arsenide system, the compound semiconductor system does not set any limit to the present invention, and the compound semiconductor devices are also fabricated in another compound semiconductor system in so far as particular features of the present invention are imparted thereto.

A compound semiconductor device includes a heterojunction bipolar transistor and a protective diode. A multi-layered compound semiconductor structure is grown on a compound semiconductor substrate, and a sub-collector region, a collector region, a base region, an emitter region and emitter cap regions are incorporated in the multi-layered compound semiconductor structure, and the multi-layered compound semiconductor structure is covered with a passivation layer. The entire upper surface of the base region is perfectly covered with the emitter region, and a base electrode penetrates the emitter region so as to be held in contact with the base region.

The compound semiconductor substrate is shared between the heterojunction bipolar transistor and the protective diode. The protective diode is also formed in a multi-layered compound semiconductor structure epitaxially grown on the compound semiconductor substrate concurrently with the multi-layered compound semiconductor structure for the heterojunction bipolar transistor. Thus, a sub-collector region, a collector region, a base region and an emitter region are incorporated in the multi-layered compound semiconductor structure for the heterojunction bipolar transistor, and two impurity regions different in conductivity type and an intrinsic semiconductor region form parts of the multi-layered compound semiconductor structure for the PIN diode. In this instance, the base region and one of the two impurity regions are formed from a compound semiconductor layer, and the sub-collector region and the intrinsic semiconductor region are formed from another compound semiconductor layer. Yet another compound semiconductor layer is shared between the sub-collector region and the other of the two impurity regions. Thus, the process sequence for the heterojunction bipolar transistor is partially overlapped with the process sequence for the protective diode, and the process for fabricating the compound semiconductor device is simple.

### First Embodiment

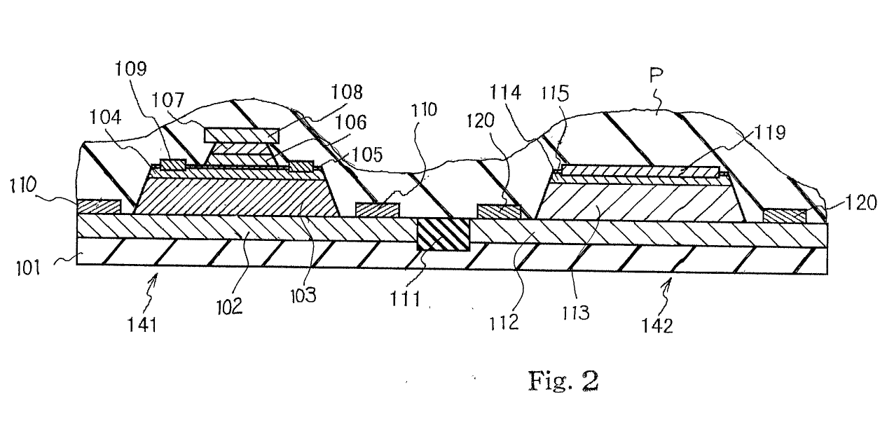

FIG. 2 shows a compound semiconductor device embodying the present invention. The compound semiconductor device is fabricated on a semi-insulating compound semiconductor substrate 101, and an isolating region 111 defines an active region assigned to a heterojunction bipolar transistor 141 and another active region assigned to a protective diode 142. In this instance, the semi-insulating compound semiconductor substrate 101 is formed of gallium arsenide, and the resistivity is equal to or greater than 10⁷ ohm-cm. The protective diode has the PIN structure. The isolating region 111 is highly resistive, and reaches the semi-insulating compound semiconductor substrate 101 so as to electrically isolate the heterojunction bipolar transistor 141 from the protective diode 142. The highly resistive region is formed through an ion-implantation. In this instance, oxygen ion is ion implanted into the surface region where the isolating region 111 is to be produced.

A multi-layered compound semiconductor structure is epitaxially grown on the active region assigned to the heterojunction bipolar transistor 141. In this instance, the heterojunction bipolar transistor 141 is of the n-p-n type, and the multi-layered compound semiconductor structure includes an n-type sub-collector region 102, an n-type collector region 103, a p-type base region 104, an n-type emitter region 105 and n-type emitter cap layers 106/107. The n-type sub-collector region 102, n-type collector region 103, p-type base region 104, n-type emitter region 105 and n-type emitter cap regions 106/107 are lattice matched with one another.

The heterojunction bipolar transistor 141 further includes a collector electrode 110 held in contact with the n-type sub-collector region 102, a base electrode 109 connected to the base region 104 and an emitter electrode 108 held in contact with the emitter cap layer 107.

The sub-collector region 102 serves as a part of the collector of the heterojunction bipolar transistor 141, and is formed of n-type gallium arsenide on the semi-insulating compound semiconductor substrate 101. The sub-collector region 102 is of the order of 1 micron thick, and the dopant concentration is 2×10¹⁸/cm³. The sub-collector region 102 is much higher in dopant concentration than the collector region 103, and the collector electrode 110 is held in contact with the sub-collector region 102 at a low contact resistance.

The n-type collector region 103 serves as another part of the collector, and is formed of n-type gallium arsenide on the n-type sub-collector region 102. The collector region 103 is of the order of 0.5 micron thick, and the dopant concentration is equal to or less than 1×10¹⁶/cm³. The entire surface of the sub-collector region 102 is not covered with the collector region 103, and the collector electrode 110 is held in contact with the exposed area of the sub-collector region 102 as shown.

The p-type base region 104 serves as the base of the heterojunction bipolar transistor 141, and is formed of p-type gallium arsenide on the n-type collector region 103. The base region 104 is of the order of 0.1 micron thick, and the dopant concentration is 1×10¹⁹/cm³. The p-type base region 104 is held in contact with the entire upper surface of the collector region 103.

Both of the collector region 103 and the base region 104 are not heavily doped with the dopant impurities. The base region 104 and the collector region 103 form a p-n junction, and a depletion layer extends from the p-n junction under the reversely biased condition. However, the lightly doped collector/base regions 103/104 permit the depletion layer widely to extend. This results in a small amount of junction capacitance at the collector-base junction. The wide depletion layer is conductive to a large breakdown voltage. However, the low dopant concentration makes the collector resistance large. In order to reduce the collector resistance, the heavily doped n-type sub-collector region 102 is provided between the collector region 103 and the collector electrode 110.

The n-type emitter region 105 serves as a part of the emitter of the heterojunction bipolar transistor 141, and is formed of indium gallium phosphide (InGaP), aluminum gallium arsenide (AlGaAs) or indium gallium arsenic phosphide (InGaAsP). The compound semiconductor for the emitter region 105, i.e., InGaP, AlGaAs or InGaAsP is lattice matched with the gallium arsenide (GaAs) for the base region 104. The emitter region 105 is 10 nanometers thick to 100 nanometers thick, and the dopant concentration ranges from 1×10¹⁷/cm³ to 6×10¹⁷/cm³. The entire upper surface of the base region 104 is covered with the emitter region 105 so that the base electrode 109 penetrates the emitter region 105 into the base region 104.

If the emitter region 105 is greater in thickness than 100 nanometers, a depletion layer is not developed, and leak current flows over the emitter-base junction. This results in that the heterojunction bipolar transistor 141 becomes uncontrollable. Thus, the upper limit of the emitter region 105 is 100 nanometers thick. On the other hand, if the emitter region 105 is less in thickness than 10 nanometers, the carrier is transported between the emitter and the base through the tunneling. This also results in leakage current, and the heterojunction bipolar transistor 141 becomes uncontrollable. The lower limit of the emitter region 105 is 10 nanometers thick. The dopant concentration between 1×10¹⁷/cm³ to 6×10¹⁷/cm³ makes the emitter region 105 fallen within the thickness range appropriately depleted.

The collector region 103, base region 104 and emitter region 105 are shaped in a rectangular parallelepiped configuration or a frustum of pyramid. The rectangular parallelepiped structure or frustum of pyramid has flat side surfaces, and any step does not take place between the collector region 103 and the base region 104 and/or between the base region 104 and the emitter region 105.

The emitter cap region 106 serves as another part of the emitter of the heterojunction bipolar transistor 141, and occupies a generally rectangular area on the upper surface of the emitter region 105. The emitter cap region 106 is narrower than the emitter region 105, and permits the manufacturer to form the base electrode 105. The emitter cap region 106 is formed of n-type GaAs, and is of the order of 0.1 micron thick. The dopant concentration is 1×10¹⁸/cm³ in this instance.

The emitter cap region 107 serves as yet another part of the emitter of the heterojunction bipolar transistor 141, and is laminated on the upper surface of the emitter cap region 106. The emitter cap region 107 is formed of n-type indium gallium arsenide, i.e., InGaAs, and is of the order of 0.1 micron thick. The dopant concentration is 1×10¹⁹/cm³ in this instance.

The emitter cap region 107 is highest in the dopant concentration in the emitter of the heterojunction bipolar transistor 141. The emitter region 105 is the lowest of the three, and the emitter cap region 106 has the dopant concentration between that of the emitter cap region 107 and the emitter region 105. Since the emitter electrode 108 is to be held in contact with the emitter cap layer at a low contact resistance, the emitter cap layer 107 is heavily doped with the n-type dopant impurity.

The emitter cap regions 106/107 form a rectangular parallelepiped configuration or a frustum of pyramid having the lower surface wider than the upper surface.

In the multi-layered compound semiconductor structure, Si imparts the n-type conductivity to the compound semiconductor, and the p-type compound semiconductor layer is doped with Zn. Other possible n-type dopant impurities are S, Se and Sn.

The collector electrode 110 is held in contact with the n-type sub-collector region 102, and the contact surface between the sub-collector 102 and the collector electrode 110 is coplanar with the contact surface between the sub-corrector 102 and the collector 103. The collector electrode 110 is formed of nickel-gold-germanium-gold, i.e., Ni/AuGe/Au, and is 0.1 micron thick. Nickel, gold-germanium alloy and gold are successively deposited on the sub-collector region 102 by using an evaporation, and, thereafter, is sintered.

The base electrode 109 projects from the peripheral area of the emitter layer 105 outside the emitter cap layer 106. The base electrode 109 is 0.3 micron thick, and is formed of platinum/titanium/platinum/gold, and is 0.3 micron thick. The platinum, titanium, platinum and gold are successively deposited on the area by using the evaporation, and are sintered so as to reach the base region 104.

The entire upper surface of the emitter cap layer 107 is covered with the emitter electrode 108, and the emitter electrode 108 sideward project from the periphery of the emitter cap layer 107. Thus, the emitter electrode 108 over-hangs the emitter cap layer 107. The emitter electrode 108 is formed of tungsten silicide, i.e., WSi, and is 0.1 micron thick. WAI and WN are available for the emitter electrode 108.

The entire upper surface of the base region 104 is covered with the emitter region 105, and forms the emitter-base junction with the entire lower surface of the emitter region 105. In this situation, current flows around the contact between the base electrode 109 and the emitter layer 105. As a result, any current does not flow the emitter electrode 108 and the base electrode 109. Another multi-layered compound semiconductor structure is epitaxially grown on the region assigned to the protective diode 142. The protective diode 142 has the PIN (P-type semiconductor-Intrinsic semiconductor-N-type semiconductor) structure, and, accordingly, includes an n-type compound semiconductor region 112, an intrinsic compound semiconductor region 113, a p-type compound semiconductor region 114 and an n-type compound semiconductor region 115. The n-type compound semiconductor region 112, intrinsic compound semiconductor region 113, p-type compound semiconductor region 114 and n-type compound semiconductor region 115 are lattice matched with one another. An electrode 119 is connected through the n-type compound semiconductor region 115 to the p-type compound semiconductor region 114, and another electrode 120 is held on contact with the n-type compound semiconductor region 112.

The n-type compound semiconductor region 112 is formed from the n-type gallium arsenide layer concurrently with the n-type sub-collector region 102. For this reason, the n-type compound semiconductor region 112 is of the order of 1 micron thick and doped with the silicon at 2×10¹⁸/cm³.

The intrinsic compound semiconductor region 113 is formed from the n-type gallium arsenide layer concurrently with the collector region 103. The intrinsic compound semiconductor region 113 and the electrode 120 are held in contact with the n-type compound semiconductor region 112. In this instance, the intrinsic compound semiconductor region 113 occupies a rectangular area. The intrinsic compound semiconductor region 113 is 0.5 micron thick, and the n-type dopant concentration is equal to or less than 1×10¹⁶/cm³.

The p-type compound semiconductor region 114 is formed from the p-type gallium arsenide layer concurrently with the p-type base region 104. The entire upper surface of the intrinsic compound semiconductor region 113 is covered with the p-type compound semiconductor region 114. The p-type compound semiconductor region 114 is 0.1 micron thick, and the p-type dopant concentration is 1×10¹⁹/cm³.

The n-type compound semiconductor region 115 is formed from the n-type compound semiconductor layer, i.e., InGaP, AlGaAs or InGaAsP concurrently with the emitter region 105. The entire upper surface of the p-type compound semiconductor region 114 is covered with the n-type compound semiconductor region 115, and the electrode 119 penetrates the central portion of the n-type compound semiconductor region 115 so as to be held in contact with the p-type compound semiconductor region 114. The n-type compound semiconductor region 115 ranges 10 nanometers thick to 100 nanometers thick, and the n-type dopant concentration is fallen within the range between 1×10¹⁷/cm³ and 6×10¹⁷/cm³.

The electrode 120 is held in ohmic contact with the n-type compound semiconductor region 112, and is formed from the nickel, gold-germanium/gold concurrently with the collector electrode 110. The electrode 120 is 0.1 micron thick. The electrode 120 serves as a cathode of the protective diode 142.

The electrode 119 is held in ohmic contact with the p-type compound semiconductor region 115, and is formed from the platinum/titanium/platinum/gold concurrently with the base electrode 109. The platinum, titanium, platinum and gold are successively deposited on the p-type gallium arsenide layer, and are sintered so as to produce the electrode 119 held in contact with the p-type compound semiconductor layer 114. The electrode 119 is 0.3 micron thick. The electrode 119 serves as an anode of the protective diode 142.

The multi-layered compound semiconductor structures are covered with a passivation layer P, which prevents the heterojunction bipolar transistor 141 and the PIN diode 142 from damages and contaminants.

The n-type compound semiconductor region 112 and p-type compound semiconductor region 114 are heavily doped with the n-type dopant impurity and p-type dopant impurity, respectively, and the intrinsic compound semiconductor region 113 is lightly doped with the n-type dopant impurity at 1×10¹⁶/cm³ or less. Thus, the lightly doped region is deemed to be intrinsic. Moreover, the intrinsic compound semiconductor layer 113 is thick, i.e., 1 micron thick. For this reason, the intrinsic compound semiconductor region 113 is completely depleted under application with a small reverse biased voltage. Although the n-type compound semiconductor region 112, p-type compound semiconductor region 115 form the PIN diode together with the completely depleted intrinsic compound semiconductor region 113, the capacitance is so small that the protective diode 142 does not have serious influence on the high-frequency characteristics of the heterojunction bipolar transistor 141. Moreover, the thick intrinsic compound semiconductor layer 113 causes the protective diode 142 to have a high breakdown voltage. The carriers are injected from the heavily doped regions so that the series resistance is low. Thus, the high breakdown voltage, small junction capacitance and low series resistance are realized in the PIN diode 142. The PIN diode is preferable for the heterojunction bipolar transistor.

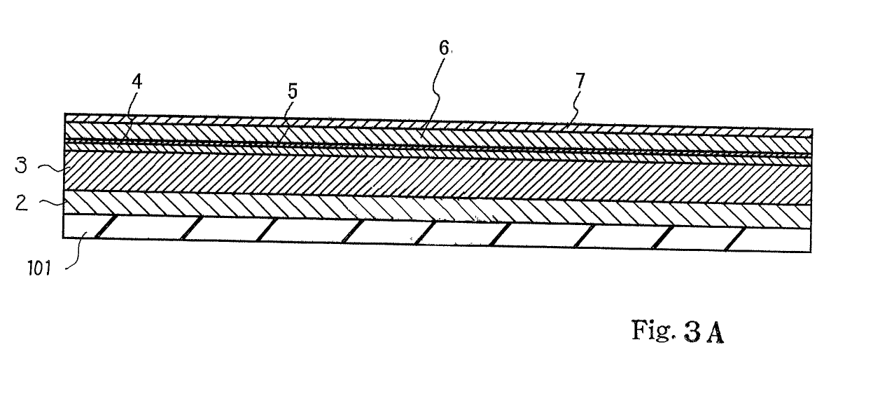

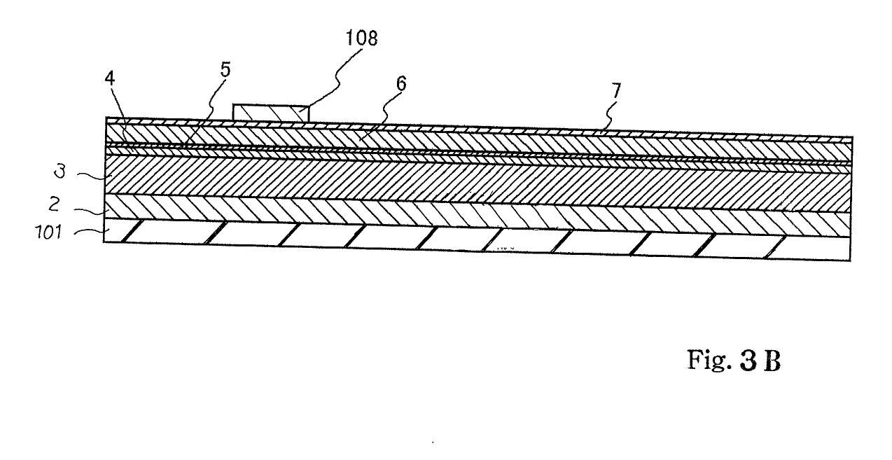

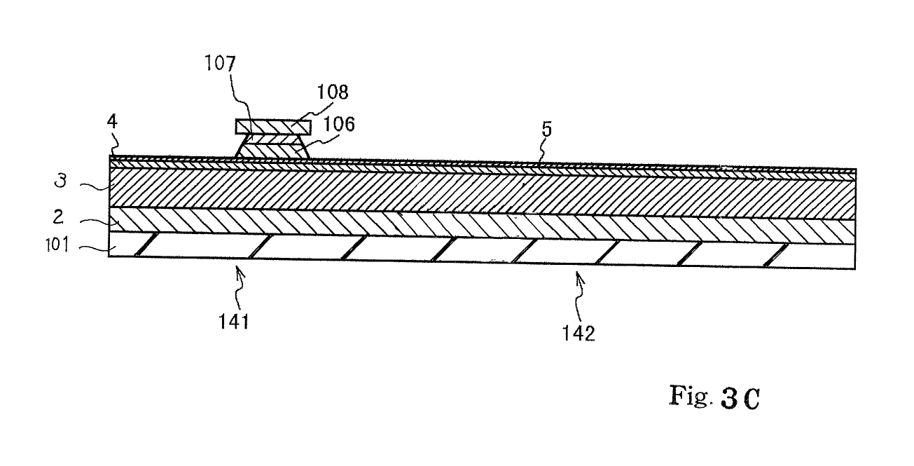

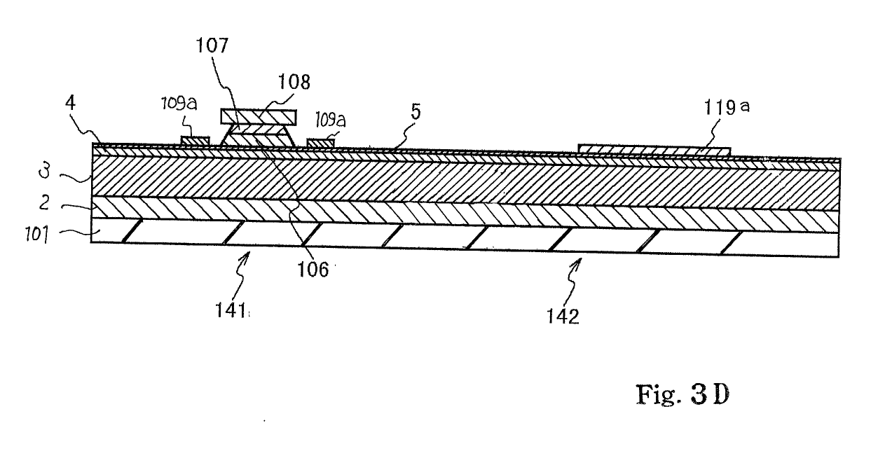

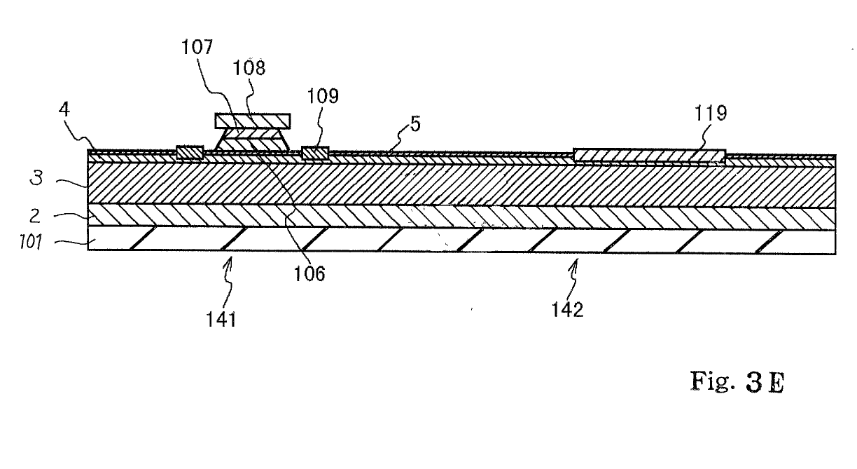

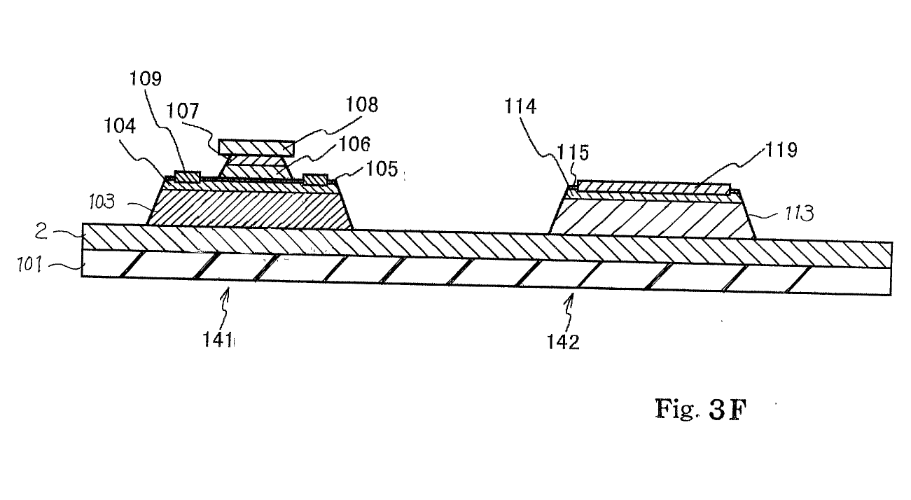

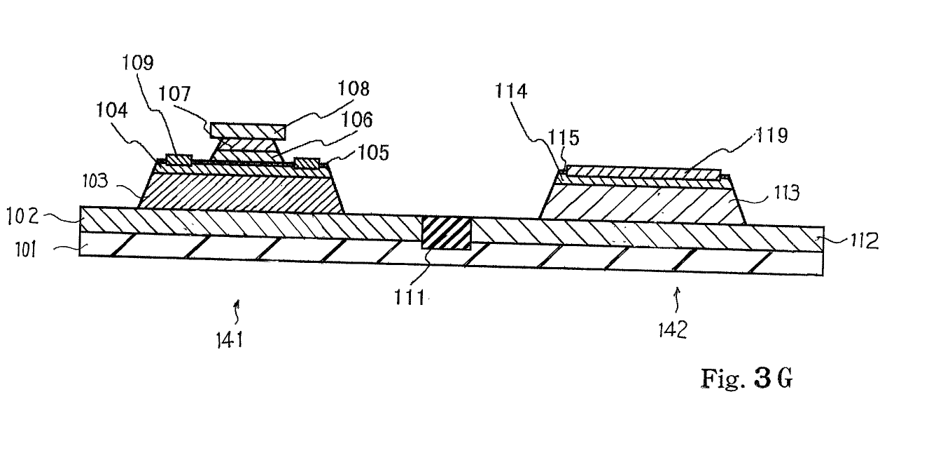

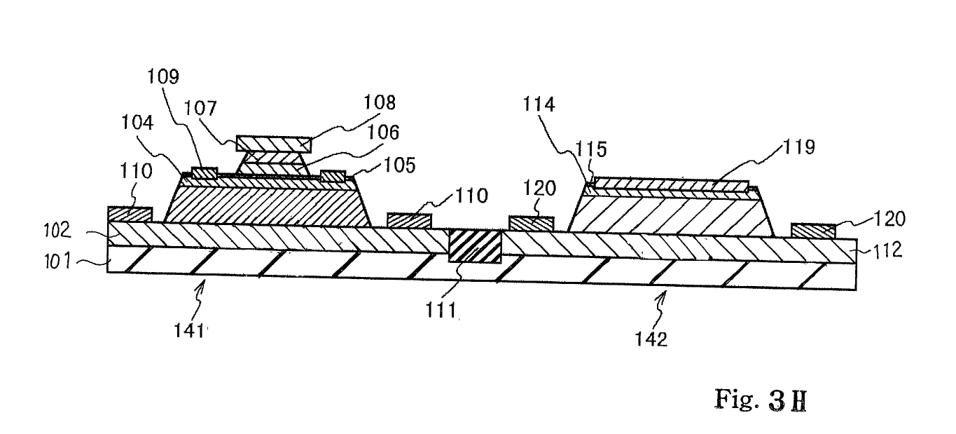

Description is hereinbelow made on a process for fabricating a compound semiconductor device embodying the present invention with reference to FIGS. 3A to 3H.

The process starts with preparation of the semi-insulating gallium arsenide substrate 101. On the major surface of the semi-insulating gallium arsenide substrate 101 are successively grown the heavily doped n-type gallium arsenide, lightly doped n-type gallium arsenide, p-type gallium arsenide, n-type compound semiconductor selected from the group consisting of InGaP, AlGaAs and InGaAsP, n-type gallium arsenide and indium gallium arsenide which form a heavily doped n-type gallium arsenide layer 2, a lightly doped n-type gallium arsenide layer 3, a p-type gallium arsenide layer 4, an n-type compound semiconductor layer 5, an n-type gallium arsenide layer 6 and an n-type indium gallium arsenide layer 7, respectively. The heavily doped n-type gallium arsenide layer 2, lightly doped n-type gallium arsenide layer 3, p-type gallium arsenide layer 4, n-type compound semiconductor layer 5, n-type gallium arsenide layer 6 and n-type indium gallium arsenide layer 7 are lattice matched with one another. A molecular beam epitaxy or a chemical vapor deposition is available for the epitaxial growth. The resultant structure is shown in FIG. 3A.

Subsequently, tungsten silicide, i.e., WSi is deposited over the entire surface of the resultant structure by using a sputtering, and forms a tungsten silicide layer on the n-type indium gallium arsenide layer 7. Photo-resist solution is spun onto the tungsten silicide layer, and is baked so as to form a photo-resist layer. A pattern image for the emitter electrode 108 is transferred from a photo-mask (not shown) to the photo-resist layer, and a latent image is formed in the photo-resist layer. The photo-resist layer is baked, and the latent image is developed. Thus, a photo-resist mask is formed on the tungsten silicide layer through photo-lithographic techniques.

Using the photo-resist mask, the tungsten silicide layer is selectively etched away so that the emitter electrode 108 is left on the tungsten silicide layer as shown in FIG. 3B.

Using the emitter electrode 108 as an etching mask, the n-type indium gallium arsenide layer 7 and the n-type gallium arsenide layer 6 are successively etched by using etchant in sulfuric acid series. Upon completion of the etching, the n-type emitter cap layers 107/106 are left on the n-type compound semiconductor layer 5 as shown in FIG. 3C. Although the emitter electrode 108 slightly overhangs the emitter cap layers 107/106, the n-type emitter cap layers 107/106 are almost as wide as the emitter electrode 108.

Subsequently, platinum, titanium, platinum and gold are successively deposited on the n-type compound semiconductor layer 5 by using the evaporation. A photo-resist etching mask (not shown) is patterned on the gold layer by using the photo-lithographic techniques. Using the photo-resist etching mask, the gold, platinum, titanium and platinum layers are selectively etched away so that metal layers 109a/119a are left on the n-type compound semiconductor layer 5 as shown in FIG. 3D. The metal layer 109a is ring shaped, and is around the n-type emitter cap layers 106/107. The metal layer 109a is separated from the n-type emitter cap layers 106/107, and occupies the area assigned to the emitter region 105. The metal layer 119a occupies the area assigned to the n-type compound semiconductor region 115, and is as wide as the n-type compound semiconductor region 115.

Subsequently, the metal layers 109a/119a are treated with heat at 300 degrees in centigrade for several minutes. The metal layers 109a/119a are diffused through the n-type compound semiconductor layer 5 into the p-type gallium arsenide layer 4. Thus, the base electrode 109 and the electrode 119 are concurrently produced through the sintering. The resultant structure is shown in FIG. 3E.

Subsequently, a photo-resist etching mask (not shown) is patterned on the resultant structure by using the photo-lithographic techniques. The areas assigned to the emitter/base/collector regions 105/104/103 and the n-type compound semiconductor/p-type semiconductor/intrinsic semiconductor regions 115/114/113 are covered with the photo-resist etching mask. Using the photo-resist etching mask, the n-type compound semiconductor layer 5, p-type gallium arsenide layer 4 and n-type gallium arsenide layer 3 are selectively etched away so that the n-type emitter/p-type base/n-type collector regions 105/104/104 and the n-type compound semiconductor/p-type compound semiconductor/intrinsic semiconductor regions 115/114/113 are left on the n-type gallium arsenide layer 2 as shown in FIG. 3F. The n-type collector region 103 is spaced from the intrinsic compound semiconductor region 113 so that the upper surface of the n-type gallium arsenide layer 2 are exposed therebetween and around the n-type collectors intrinsic compound semiconductor regions 103/113.

Subsequently, a photo-resist ion-implantation mask (not shown) is prepared on the resultant structure, and an area assigned to the isolating region 111 is exposed to an opening of the photo-resist ion-implantation mask. Oxygen ion is implanted into the n-type gallium arsenide layer 2, and is driven into the semi-insulating gallium arsenide substrate 101. The implanted oxygen forms the isolating region 111, and the n-type gallium arsenide layer 2 is divided into the n-type sub-collector region 102 and the n-type compound semiconductor region 112. The isolating region 111 makes the heterojunction bipolar transistor 141 isolated from the protective diode as shown in FIG. 3G.

Subsequently, a photo-resist mask (not shown) is patterned through the photo-lithographic techniques, and areas assigned to the collector electrode 110 and the electrode 120 are exposed to openings of the photo-resist mask. Nickel, gold-germanium alloy and gold are deposited thereon by using the evaporation, and are layered on the areas and the photo-resist mask. The photo-resist mask is removed so that the metal layers are left on the areas assigned to the collector electrode 110 and the electrode 120. The metal layers are subjected to heat treatment, and the collector electrode 110 and the electrode 120 are produced on the sub-collector region 102 and the n-type compound semiconductor region 112 through the sintering as shown in FIG. 3H.

Finally, insulating material is deposited over the entire surface of the resultant structure, and forms the passivation layer P.

As will be understood, the protective diode 142 is fabricated on the active region through the steps for forming the sub-collector/collector/base regions 102/103/104 and the base and collector electrodes 109/110, and any additional step is not required for the fabrication of the protective diode 142. The n-type gallium arsenide layer 2, n-type gallium arsenide layer 3 and p-type gallium arsenide layer 4 are shared between the heterojunction bipolar transistor 141 and the protective diode 142, and the electrodes 119 and 120 are formed concurrently with the base and collector electrodes 109/110. Only the photo-masks used in the photo-lithography are to be redesigned. Thus, the protective diode 142 is integrated on the semi-insulating substrate 101 together with the heterojunction bipolar transistor 141 without sacrifice of the production cost.

The entire upper surface of the base region 104 is covered with the emitter region 105 so that the leakage current does not flow between the base electrode 109 and the emitter electrode 108 through the passivation layer P.

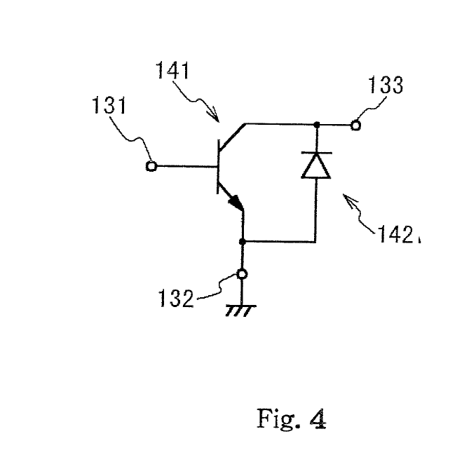

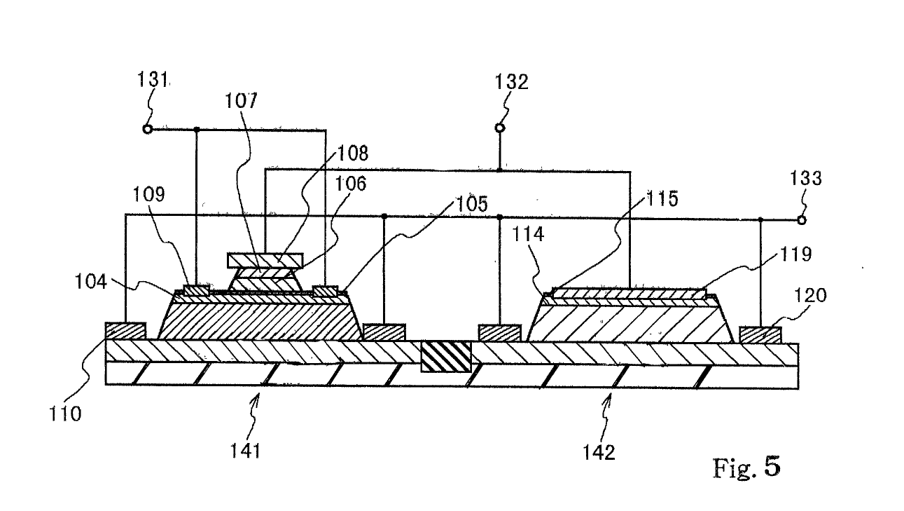

The behavior of the compound semiconductor device is hereinbelow described with reference to FIGS. 4 and 5. As shown in FIG. 4, a signal input node 131 is connected to the base electrode 109, and a signal output node 133 is connected to the collector electrode 110. The emitter electrode 108 is connected through a node 132 to the ground. Thus, the heterojunction bipolar transistor 141 serves as a common-emitter amplifier.

The emitter electrode 108 is further connected to the electrode 119, i.e., the anode of the protective diode 142, and the electrode 120 or the cathode is connected to the collector electrode 110. Thus, the protective diode 142 is connected between the emitter and the collector. The connections between the heterojunction bipolar transistor 141 and the protective diode 142 are implemented by metallization formed in the passivation layer P as shown in FIG. 5.

While the heterojunction bipolar transistor 141 is operating in the normal condition, the protective diode 142 is turned off, and do not permit any current to flow therethrough. The protective diode 142 has the PIN structure. The capacitance is small, the withstanding voltage is high and the series resistance is low. The protective PIN diode 142 does not make the time constant large so that the heterojunction bipolar transistor 141 maintains the good high-frequency characteristics. However, when strong static surge is applied to the node 132, the emitter node 132 rises to an extremely high potential level. Then, the protective diode 142 turns on, and the extremely high potential is discharged through the protective diode 142 to the signal output node 133. Thus, the protective diode 142 prevents the heterojunction bipolar transistor 141 from serious damage, and enhances the reliability of the heterojunction bipolar transistor 141.

### Second Embodiment

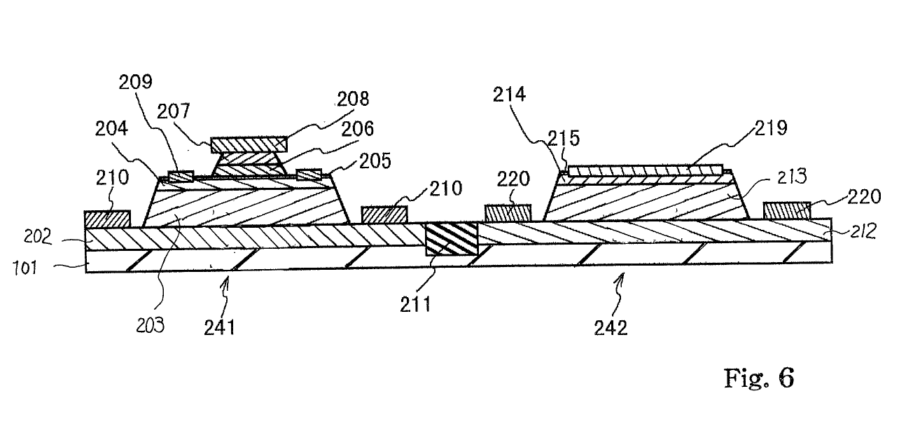

FIG. 6 shows another compound semiconductor device embodying the present invention. The compound semiconductor device includes a heterojunction bipolar transistor 241 and a protective diode 242, which are integrated on a single semi-insulating compound semiconductor substrate 101. The heterojunction bipolar transistor 241 is electrically isolated from the protective diode 242 by means of an isolating region 211. A difference between the first embodiment and the second embodiment is the collector. In the second embodiment, the collector is implemented by a compound semiconductor layer wider in band gap than the compound semiconductor layer, i.e., GaAs for the collector of the heterojunction bipolar transistor 141. In this instance, the compound semiconductor for the collector is indium gallium phosphide (InGaP) or aluminum gallium arsenide (AlGaAs).

The semi-insulating compound semiconductor substrate 101 and the isolating region 211 are similar to those of the first embodiment, and no further description is incorporated hereinbelow.

The heterojunction bipolar transistor 241 has a multi-layered compound semiconductor structure, and a sub-collector region 202, a collector region 203, a base region 204, an emitter region 205, emitter cap layers 206/207 are built in the multi-layered compound semiconductor structure. An emitter electrode 208, a base electrode 209 and a collector electrode 210 are held in contact with the emitter cap layer 207, the base region 204 and the sub-collector region 202, respectively, and the heterojunction bipolar transistor 241 and the protective diode 242 are covered with a passivation layer (not shown). The entire upper surface of the base region 204 is covered with the emitter region 205 so as to prevent the heterojunction bipolar transistor 241 from leakage current flowing between the base electrode 209 and the emitter electrode 208.

The n-type collector region 203 serves as the collector of the heterojunction bipolar transistor 241 together with the n-type sub-collector region 202, and occupies most of the area assigned to the heterojunction bipolar transistor 241. In this instance, the n-type collector region 203 occupies a rectangular area. The n-type collector region 203 is formed of n-type indium gallium phosphide, i. e., InGaP lattice matched with the n-type gallium arsenide for the sub-collector region 202. Otherwise, the n-type collector region 203 may be formed of AlGaAs or InGaAsP. The collector region 103 is of the order of 1 micron thick, and the dopant concentration is equal to or less than 1×10¹⁶/cm³. The entire surface of the sub-collector region 202 is not covered with the collector region 203, and the collector electrode 210 is held in contact with the exposed area of the sub-collector region 202 as shown.

The sub-collector region 202, base region 204, emitter layer 205, emitter cap layers 206/207, emitter electrode 208, base electrode 209 and collector electrode 210 are similar to those of the first embodiment, and detailed description is omitted for avoiding repetition.

Another multi-layered compound semiconductor structure is epitaxially grown on the region assigned to the protective diode 242. The protective diode 242 has the PIN (P-type semiconductor-Intrinsic semiconductor-N-type semiconductor) structure, and, accordingly, includes an n-type compound semiconductor region 212, an intrinsic compound semiconductor region 213, a p-type compound semiconductor region 214 and an n-type compound semiconductor region 215. The n-type compound semiconductor region 212, intrinsic compound semiconductor region 213, p-type compound semiconductor region 214 and n-type compound semiconductor region 215 are lattice matched with one another. An electrode 219 is connected through the n-type compound semiconductor region 215 to the p-type compound semiconductor region 214, and another electrode 220 is held on contact with the n-type compound semiconductor region 212.

The intrinsic compound semiconductor region 213 is formed of the compound semiconductor same as that for the collector region 203, and occupies most of the area assigned to the protective diode 242. In this instance, the intrinsic compound semiconductor region 213 occupies a rectangular area. The intrinsic compound semiconductor region 213 is formed of InGaP, AlGaAs or InGaAsP lattice matched with the gallium arsenide for the n-type compound semiconductor region 212. The n-type dopant concentration is equal to or less than 1×10¹⁶/cm³.

The n-type compound semiconductor region 212, p-type compound semiconductor region 214, n-type compound semiconductor region 215 and electrodes 219/220 are similar to those of the first embodiment, and detailed description is omitted for avoiding repetition.

The compound semiconductor device implementing the second embodiment is fabricated on the semi-insulting substrate 101 through a process similar to that of the first embodiment except for the epitaxial growth. Although the lightly-doped n-type gallium arsenide is grown for the collector and intrinsic compound semiconductor regions in the process implementing the first embodiment, indium gallium phosphide, aluminum gallium arsenide or indium gallium arsenic phosphide is epitaxially grown for the collector and intrinsic compound semiconductor regions 203/213 in the process for the second embodiment.

The electrical connections between the heterojunction bipolar transistor 241 and the protective diode 241 are similar to those of the first embodiment, and no further description is incorporated hereinbelow.

All the advantages of the first embodiment are also achieved by the compound semiconductor device implementing the second embodiment. Additionally, the protective diode 242 exhibits the withstanding voltage, i.e., anti-surge characteristics larger than the protective diode 142, because the compound semiconductor, i.e., InGaP, AlGaAs or InGaAsP has the band gap wider than that of the gallium arsenide. Thus, the compound semiconductor enhances the reliability of the compound semiconductor device.

As will be appreciated from the foregoing description, the entire upper surface of the base region is covered with the emitter region so that leakage current hardly flows between the base electrode and the emitter electrode. This results in improvement in reliability. The protective diode is fabricated on the substrate concurrently with the heterojunction bipolar transistor without any additional step. For this reason, the production cost for the compound semiconductor device according to the present invention is lower than the production cost for the prior art discrete devices.

Although particular embodiments of the present invention have been shown and described, it will be apparent to those skilled in the art that various changes and modifications may be made without departing from the spirit and scope of the present invention.

Plural heterojunction bipolar transistors may be integrated together with plural protective diodes on a single compound semiconductor substrate.

A heterojunction bipolar transistor may have the p-n-p structure. In this instance, the sub-collector region, collector region and emitter region are p-type, and the base region is n-type. Accordingly, the protective PIN diode is implemented by the lamination of a p-type compound semiconductor region, intrinsic compound semiconductor region, n-type compound semiconductor region and p-type compound semiconductor region.

Another sort of compound semiconductor diode may serves as the protective diode. Another sort of circuit element such as, for example, a transistor or capacitor may be formed in another multi-layered compound semiconductor structure.

What is claimed is:

1. A compound semiconductor device fabricated on a substrate, comprising:
a first multi-layered compound semiconductor structure grown on a first region of said substrate assigned to a heterojunction bipolar transistor, and providing a base region grown on a collector region for forming a collector-base junction and having an upper surface and an emitter region grown on said base region for forming a base-emitter junction substantially as wide as said upper surface of said base region, said heterojunction bipolar transistor further including a collector electrode electrically connected to said collector region, a base electrode formed on said emitter region and penetrating therethrough so as to be in contact with said base region and an emitter electrode electrically connected to said emitter region;
a second multi-layered compound semiconductor structure grown on a second region of said substrate assigned to another element, and electrically isolated from said first multi-layered compound semiconductor structure; and
a passivation layer covering said first and second multi-layered compound semiconductor structures.

2. The compound semiconductor device as set forth in claim 1, in which said another element is a protective diode connected to said heterojunction bipolar transistor in order to prevent said heterojunction bipolar transistor from static surge.

3. The compound semiconductor device as set forth in claim 2, in which said protective diode has a substantially intrinsic compound semiconductor region sandwiched between an n-type compound semiconductor region and a p-type compound semiconductor region.

4. The compound semiconductor device as set forth in claim 3, in which said n-type compound semiconductor region and said p-type compound semiconductor region are connected to said collector region and said emitter region, respectively, so as to discharge said static surge without passing through said heterojunction bipolar transistor.

5. The compound semiconductor device as set forth in claim 1, in which said emitter region is formed of a first compound semiconductor having a band gap wider than a band gap of a second compound semiconductor for said base region and said collector region.

6. The compound semiconductor device as set forth in claim 5, in which said first compound semiconductor is gallium arsenide, and said second compound semiconductor is selected from the group consisting of indium gallium phosphide, aluminum gallium arsenide and indium gallium arsenic phosphide.

7. The compound semiconductor device as set forth in claim 1, in which said emitter region, said base region and said collector region are respectively formed of a first compound semiconductor having a first band gap, a second compound semiconductor having a second band gap and a third compound semiconductor having a third band gap, and said first band gap and said third band gap are wider than said second band gap.

8. The compound semiconductor device as set forth in claim 5, in which said second compound semiconductor is gallium arsenide, and said first compound semiconductor and said third compound semiconductor are selected from the group consisting of indium gallium phosphide, aluminum gallium arsenide and indium gallium arsenic phosphide and the group consisting of indium gallium phosphide and aluminum gallium arsenide.

9. The compound semiconductor device as set forth in claim 1, in which said first multi-layered compound semiconductor structure includes a sub-collector region of a first conductivity type grown on said first region, said collector region of said first conductivity type grown on said sub-collector region and heavier in dopant concentration than said sub-collector region, said base region of a second conductivity type opposite to said first conductivity type grown on said collector region, said emitter region of said first conductivity type grown on said base region and an emitter cap structure of said first conductivity type grown on a certain area of said emitter region, and said emitter electrode and said collector electrode are respectively held in contact with an entire upper surface of said emitter cap structure and an exposed area of said sub-collector region.

10. The compound semiconductor device as set forth in claim 9, in which said collector region has a dopant concentration equal to or less than 1×10¹⁶/cm ³.

11. The compound semiconductor device as set forth in claim 9, in which said emitter region has a thickness fallen within the range between 10 nanometers and 100 nanometers and a dopant concentration fallen within the range between 1×10¹⁷/cm³ and 6×10¹⁷/cm³.

12. The compound semiconductor device as set forth in claim 1, in which said first multi-layered compound semiconductor structure includes a sub-collector region of a first conductivity type grown on said first region, said collector region of said first conductivity type grown on said sub-collector region, said base region of a second conductivity type opposite to said first conductivity type grown on said collector region, said emitter region of said first conductivity type grown on said base region and an emitter cap structure of said first conductivity type grown on a certain area of said emitter region, and said emitter electrode and said collector electrode are respectively held in contact with an entire upper surface of said emitter cap structure and an exposed area of said sub-collector region, and
said second multi-layered compound semiconductor structure serves as a protective diode with a PIN structure including a first compound semiconductor region of said first conductivity type grown on said second region of said substrate and separated from said sub-collector region by an isolating region, a second compound semiconductor region of said first conductivity type grown on said first compound semiconductor region and as light in dopant concentration as said collector region, a third compound semiconductor region of said second conductivity type grown in said second compound semiconductor region and as heavy in dopant concentration as said base region and a fourth compound semiconductor region of said first conductivity type grown on said third compound semiconductor region and as heavy in dopant concentration as said emitter region.

13. The compound semiconductor device as set forth in claim 12, in which said first compound semiconductor region and said third compound semiconductor region are electrically connected to said collector electrode and said emitter electrode, respectively, in order to prevent said heterojunction bipolar transistor from static surge.

13. A process for fabricating a compound semiconductor device, comprising the steps of:
a) epitaxially growing a plurality of compound semiconductor layers a substrate;
b) shaping said plurality of compound semiconductor layers into plural multi-layered compound semiconductor structures on respective regions of said substrate so as to form an emitter electrode electrically connected to an emitter region incorporated in one of said plural multi-layered compound semiconductor structures, a base electrode formed on said emitter region layered on an entire upper surface of a base region and penetrating said emitter region so as to be in contact with said base region, a collector electrode electrically connected to a collector region and other electrodes connected to certain compound semiconductor regions of another of said plural multi-layered compound semiconductor structures; and
c) covering said plural multi-layered compound semiconductor structure with a passivation layer so that said emitter region prevents said entire surface of said base region from being in contact with said passivation layer.

14. The process as set forth in claim 13, in which said substrate is formed of semi-insulating compound semiconductor, and said plurality of compound semiconductor layers are successively grown on said substrate by using an epitaxial growth technique.

15. The process as set forth in claim 14, in which said epitaxial growth technique is selected from the group consisting of a molecular beam epitaxy and a chemical vapor deposition.

16. The process as set forth in claim 13, in which said another of said plural multi-layered compound semiconductor structure serves as a PIN diode having a first compound semiconductor region grown on said substrate and serving as one of electrodes of said PIN diode, a second compound semiconductor region grown on said first compound semiconductor region and completely depleted under application of a reverse bias voltage, a third compound semiconductor region grown on said second compound semiconductor region and serving as the other of said electrodes of said PIN diode and a fourth compound semiconductor region grown on said third compound semiconductor region.

17. The process as set forth in claim 16, in which said step b) includes the sub-steps of
b-1) forming said emitter electrode on said plurality of compound semiconductor layers,
b-2) selectively etching said plurality of compound semiconductor layers by using said emitter electrode as an etching mask so that a first predetermined compound semiconductor layer to be formed into said emitter region and said fourth compound semiconductor region is exposed around an emitter cap structure under said emitter electrode,
b-3) patterning a conductive layer into conductive strips on an area of said first predetermined compound semiconductor layer assigned to said base electrode and another area of said first predetermined compound semiconductor layer assigned to a first electrode of said PIN diode,
b-4) heating said conductive strips so as to cause said conductive strips to penetrate said first predetermined compound semiconductor layer for reaching a second predetermined compound semiconductor layer beneath said first predetermined compound semiconductor layer, thereby producing said base electrode and said first electrode,
b-5) patterning said first predetermined compound semiconductor layer, said second predetermined compound semiconductor layer and a third predetermined compound semiconductor layer beneath said second predetermined compound semiconductor layer into said emitter and fourth compound semiconductor regions, said base and third compound semiconductor regions and said collector and second compound semiconductor regions, and
b-6) concurrently forming said collector electrode and a second electrode of said PIN diode on a sub-collector region under said collector region and on said first compound semiconductor region exposed around said second compound semiconductor region.

18. The process as set forth in claim 17, in which said step b) further including the step b-7) of forming an isolating region between said one of said plural multi-layered compound semiconductor structure and said another of said plural multi-layered compound semiconductor structure between said step b-5) and said step b-6).

19. The process as set forth in claim 18, in which a fourth predetermined compound semiconductor layer for said sub-collector and first compound semiconductor regions, said third predetermined compound semiconductor layer and said second predetermined compound semiconductor layer are respectively formed of heavily doped gallium arsenide of a first conductivity type, lightly doped gallium arsenide of said first conductivity type and heavily doped gallium arsenide of a second conductivity type opposite to said first conductivity type, and said first predetermined compound semiconductor layer is formed of compound semiconductor selected from the group consisting of InGaP, AlGaAs and InGaAsP.

20. The process as set forth in claim 19, in which oxygen is ion implanted into said fourth predetermined compound semiconductor layer for producing said isolating region in said step b-7).

21. The process as set forth in claim 18, in which a fourth predetermined compound semiconductor layer for said sub-collector and first compound semiconductor regions and said second predetermined compound semiconductor layer are respectively formed of heavily doped gallium arsenide of a first conductivity type and heavily doped gallium arsenide of a second conductivity type opposite to said first conductivity type, and said first predetermined compound semiconductor layer and said third predetermined compound semiconductor layer are formed of compound semiconductor selected from the group consisting of InGaP, AlGaAs and InGaAsP and compound semiconductor selected from the group consisting of InGaP and AlGaAs, respectively.

22. The process as set forth in claim 21, in which oxygen is ion implanted into said fourth predetermined compound semiconductor layer for producing said isolating region in said step b-7).
